(19) United States
(12) Patent Application Publication
(10) Pub. No.: US 2012/0196131 A1
(43) Pub. Date: Aug. 2, 2012

(54) Assembly for fabricating a structure having a crystalline film, method of making the assembly, crystalline film structure produced by the assembly and crystalline films

(76) Inventor: Louay Eldada, Austin, TX (US)

(21) Appl. No.: 12/931,285

(22) Filed: Jan. 28, 2011

(51) Int. Cl. B32B 9/04; H01L 21/20; B32B 15/04

(52) U.S. Cl. 428/411.1; 428/457; 428/688; 428/689; 438/478; 257/E21.09

(57) ABSTRACT

An assembly for fabricating a structure having a crystalline film, includes a rigid substrate, a conductive layer in operative contact with the rigid substrate, a first precursor material of the crystalline film in operative contact with the conductive layer, and a flexible substrate include a contact surface, wherein the contact surface of the flexible substrate is in operative contact with the first precursor material opposite from the conductive layer. A crystalline film structure, crystalline film structure produced thereby, methods of making the assembly and the crystalline film structure, respectively, are also described herein.

### FIELD OF THE INVENTION

The present invention relates to material processing, and more particularly an assembly for fabricating a structure having a crystalline film, crystalline film structures produced thereby, and method of making the assemblies and crystalline film structures, respectively.

### BACKGROUND OF THE INVENTION

Semiconductor materials in the form of crystalline solids provide the basis for many applications in modern electronics including transistors, solar cells, diodes, and other devices.

Semiconductor materials containing elements, binary compounds, ternary compounds and multinary compounds selected from Group I, Group II, Group III, Group IV, and Group VI of the periodic table have been of interest in photovoltaic applications. Such semiconductor materials are used as absorber materials, a critical component in generating electricity from light. One particular form of absorber material is composed of combinations of copper, indium, gallium, selenium and sulfur (CIGS(S)). CIGS(S) can be processed to form nanostructures in crystalline thin films.

Prior art methods of fabricating absorber materials (e.g., CIGS(S)) involve depositing a precursor material on a conductive metal layer (e.g., molybdenum) which is previously deposited on a rigid base substrate (e.g., 3-mm thick soda-lime glass). The conductive metal layer provides an electrical back contact electrode in a thin film solar cell or module. Prior to processing the precursor materials into the absorber material comprising a nanostructured crystalline film, a rigid tool substrate is placed in abutting contact with the deposited precursor materials. The rigid tool substrate may optionally have deposited thereon the same or different precursor material, which is placed in contact with the precursor material of the rigid base substrate.

The rigid base and tool substrates are brought together with the precursor materials sandwiched therebetween. While the precursor materials are retained between the rigid substrates, the precursor materials are then processed chemically and/or physically (e.g., sintering in situ) to produce the desired p-type absorber material in the form of a nanostructured crystalline film. After chemical and/or physical processing, the rigid tool substrate is removed. The resulting p-type absorber material supported on the conductive metal layer-coated rigid base substrate is thereafter used to complete fabrication of a thin film solar cell or module as known in the art.

Examples of the above process are taught and described, for example, in U.S. Pat. Nos. 6,736,986; 6,881,647; 7,148,123; 6,787,012; 7,163,608; 6,500,733; 6,797,874; and 6,720239, the contents of which are incorporated herein by reference. Although rigid tool and base substrates are widely used in the manufacture of thin film solar cells or modules, such rigid tool and base substrates have inherent, uneven, rough surfaces at atomic levels. The surface roughness of the rigid substrates prevents full contact with the surfaces of the precursor materials. The presence of non-contact areas may result in undesirable defects in the thin films, reducing the efficiency of devices utilizing such thin films such as solar cells or modules.

Such defects substantially reduce the efficiency of photon energy absorption and electrical current generation and collection, and adversely affect the performance of thin film solar cells or modules fabricated using rigid substrates. To reduce surface roughness, it is known to heat the rigid substrates to their softening point. While such heating can smooth the surface of such substrate, the temperatures needed to achieve softening are usually detrimental to the precursor materials, resulting in poorly performing absorber materials.

In view of the foregoing problems, there is a need for an assembly for fabricating a structure having a crystalline film and method of making the same, which substantially reduces defects in the crystalline film typically associated with the use of rigid substrates in the manner known in the prior art. There is a need for an assembly for fabricating a structure having a crystalline film and method of making the same, which provides, in a cost-effective manner, which addresses the problems identified above including eliminating or at least substantially reducing the extent of defects typically associated with the use of rigid substrates.

### SUMMARY OF THE INVENTION

The present invention relates generally in part to an assembly for fabricating a structure having a crystalline film. The present invention also provides improved crystalline films with improved energy transmitting efficiencies because of the reduction in defects typically associated with the use of rigid substrates. Also forming part of the present invention, are methods of making the assembly and methods of producing crystalline films.

The assembly of the present invention includes a rigid substrate, a conductive layer being in operative contact with the rigid substrate, a first precursor material of the crystalline film being in operative contact with the conductive layer, and a flexible substrate including a contact surface, where the contact surface of the flexible substrate is in operative contact with the first precursor material opposite from the conductive layer. The assembly of the present invention is configured to substantially reduce defects in the resulting crystalline film typically associated with the use of rigid substrates. The resulting crystalline film exhibits improved optical energy absorption, electronic properties, and optical to electrical energy conversion efficiencies.

In the present invention, the flexible substrate used in the manner described herein provides a cost-effective means for enhanced pressure control, structure transfer, and/or surface behavior during processing of the precursor materials into corresponding crystalline films.

In one aspect of the present invention, there is provided an assembly for fabricating a structure having a crystalline film, which includes:

a rigid substrate;

a conductive layer being in operative contact with the rigid substrate;

a first precursor material of the crystalline film being in operative contact with the conductive layer; and

a flexible substrate including a contact surface, the contact surface of the flexible substrate being in operative contact with the first precursor material opposite from the conductive layer.

In another aspect of the present invention, there is provided a crystalline film structure comprising:

a rigid substrate;

a conductive layer being in operative contact with the rigid substrate; and

a first precursor material of the crystalline film having a flexible substrate treated surface in operative contact with the conductive layer.

In another aspect of the present invention, there is provided a method of making a structure having a crystalline film, which includes the steps of:

obtaining a rigid substrate having a conductive layer disposed in operative contact therewith;

applying a first precursor material of the crystalline film on the conductive layer in operative contact therebetween; and

applying a flexible substrate having a contact surface, wherein the contact surface is in operative contact with the first precursor material opposite from the conductive layer;

processing the first precursor material into the crystalline film; and

removing the flexible substrate.

In a further aspect of the present invention there is provided a crystalline film structure made by the above method.

In another aspect of the present invention, there is provided a method of making an assembly for fabricating a structure having a crystalline film, which includes the steps of:

obtaining a rigid substrate having a conductive layer disposed in operative contact therewith;

applying a first precursor material of the crystalline film on the conductive layer in operative contact therebetween; and

applying a flexible substrate having a contact surface, wherein the contact surface is in operative contact with the first precursor material opposite from the conductive layer.

### BRIEF DESCRIPTION OF THE DRAWINGS

The following drawings are illustrative of embodiments of the present invention and are not intended to limit the invention as encompassed by the claims forming part of the application.

FIG. 1A is a schematic side view of an assembly for fabricating a structure having a crystalline film in accordance with one embodiment of the present invention;

FIG. 1B is a schematic side view of a structure having a crystalline film with a flexible substrate removed in accordance with one embodiment of the present invention; and

FIG. 2 is a schematic flow diagram illustrating a method of making an assembly for fabricating a structure having a crystalline film in accordance with one embodiment of the present invention.

### DETAILED DESCRIPTION OF THE INVENTION

The present invention is generally directed to an assembly for fabricating a structure having a crystalline film, crystalline film structures produced thereby, methods of making the assembly and crystalline film structure, respectively. The assembly of the present invention includes a rigid substrate, a conductive layer being in operative contact with the rigid substrate, a first precursor material of the crystalline film being in operative contact with the conductive layer, and a flexible substrate including a contact surface, where the contact surface of the flexible substrate is in operative contact with the first precursor material opposite from the conductive layer. The assembly of the present invention is configured to produce a crystalline film with substantially reduce defects typically associated with the use of rigid substrates. The resulting crystalline film exhibits improved electronic properties and energy transmission efficiencies.

In the present invention, the flexible substrate used in the manner described herein provides a cost-effective means for enhanced pressure control, structure transfer, and/or surface behavior during processing of the precursor materials into corresponding crystalline films.

The method of the present invention is used for making the present assembly which includes a crystalline film exhibiting a desired crystalline structure (i.e., monocrystalline or polycrystalline) with fewer defects than is typically associated with known assemblies using rigid substrates in the absence of the present invention. The method utilizes a precursor material which may be deposited as one or more layers on a rigid substrate and overlaid with a flexible substrate prior to processing as will be described hereinafter.

The assembly and methods of the present invention will be described in context of the fabrication of a semiconductor layer, coating or film for use in, for example, a photovoltaic device and/or system. However, it will be understood that the process of the present invention can be used in various applications including, but not limited to, the fabrication of a composition layer, coating or film that may be used in a subassembly, which in turn may be used in a larger assembly, or the fabrication of a superconductor layer, coating or film for use in, for example, an electronic device and/or system.

In one embodiment of the present invention, an assembly for fabricating a structure having a crystalline film, includes a rigid substrate, a conductive layer being in operative contact with the rigid substrate, a first precursor material of the crystalline film being in operative contact with the conductive layer, and a flexible substrate including a contact surface, where the contact surface of the flexible substrate is in operative contact with the first precursor material opposite from the conductive layer. Optionally, the contact surface of the flexible substrate may further include a second precursor material of the crystalline film in operative contact with the first precursor material. Thus, the present assembly employs a flexible substrate, not a rigid substrate, for operative contact with the precursor material.

The term “rigid substrate” as used herein refers to any material compatible with the process conditions of the present invention which maintains its shape without bending upon the application of the degree of force used when the flexible substrate is placed in operable contact with the precursor material. If a sufficient force is applied the rigid substrate will generally break. The material of the rigid substrate may be preferably selected from glass, ceramic, metal, and combinations thereof. More preferably, the substrate is glass such as, for example, soda-lime glass. The rigid substrate when used in photovoltaic applications generally has a thickness in the range of from about 0.5 mm to 5 mm, and preferably from about 1 to 3 mm. It will be noted that certain materials may be rigid within the definition used herein at certain minimum thickness, but may be classified as “flexible” if used in lower thickness.

The term “flexible substrate” as used herein refers to any substrate compatible with the process conditions of the present invention exhibiting low resistance to deformation upon the application of force and capable of conforming to the surface of the precursor material to achieve operative contact at the atomic level, while remaining relatively inert and compatible with the precursor material. The flexible substrate operates to provide pressure control, structure transfer, and/or surface behavior during processing of the precursor materials into corresponding crystalline films.

Preferably, the flexible substrate is selected to withstand reaction temperatures normally encountered in the processing of precursor materials, and exhibit good transmission of energy (e.g., thermal, infrared, optical, electrical) suitable for processing the underlying precursor material. The flexible substrate may be selected from glass, ceramics, polymers, metals, and the like.

In a preferred embodiment of the present invention, the flexible substrate includes a contact surface for contacting the precursor material where the contact surface includes nanostructures to promote the formation of enhanced nanodomains with high contrast between corresponding compositions of the domains (e.g., Cu-rich α-domains and Cu-poor β-domains in CIGS-based crystalline films). The term “nanostructures” as used herein refers to nanoscale protrusions or protrusions disposed on the contact surface of the flexible substrate.

The term “conductive layer” as used herein refers to a continuous or patterned layer of a conductive material such as a metal, which is disposed between the rigid substrate and the precursor material. The thickness of the conductive layer is typically in the range of from about 0.1 μm to 1.0 μm, and preferably from about 0.3 μm to 0.5 μm. The conductive metal may be selected from molybdenum, titanium, tungsten, tantalum and the like.

The term “precursor material” as used herein refers to any element or compound for processing into a crystalline film (i.e., monocrystalline or polycrystalline) via suitable processing means including heating. The precursor material may be in the form of one or more layers each selected from a chemical element, a binary compound, a ternary compound, a multinary compound, or combinations thereof. The precursor material is preferably in the form of a continuous film, which may be placed, applied, coated, supported or deposited on a conductive layer on a rigid substrate. The precursor material typically has a thickness in the range of from about 0.5 μm to 4 μm, preferably from about 1.5 μm to 2.5 μm.

The term “operable contact” as used herein refers to the contact between corresponding layers made in a manner such that the adjacent layers are securely retained to one another during the formation of a desired final product. The operable contact may be made by physical or chemical means or the like.

In the present invention, the precursor material may be selected from any chemical element or compound capable of assuming a crystalline structure (moncrystalline or polycrystalline) upon interaction and/or reaction of the components in the precursor material. The layers of precursor material may be composed of the same or different chemical compositions. In a preferred embodiment of the present invention, the precursor material is selected from elements of Group I, Group II, Group III, Group IV and Group VI in the periodic table, and mixtures thereof.

Examples of Group I elements include copper, silver, and gold. Examples of Group II elements include zinc and cadmium. Examples of Group III elements include indium, gallium, and aluminum. Examples of Group IV elements include tin, germanium, and silicon. Examples of Group VI elements include selenium, sulfur, and tellurium.

More preferred combinations of precursor material include those selected from:

a) Group I, Group III and Group VI (e.g., copper indium gallium selenide (CIGS));

b) Group II and Group VI (e.g., cadmium telluride (CdTe)); and

c) Group I, Group II, Group IV and Group VI (e.g., copper zinc tin sulfide (CZTS)).

The term “crystalline film” also referred to as “precursor product”, or “reaction product” is the material formed from the interaction between the components of the precursor material under reaction promoting conditions of the present invention.

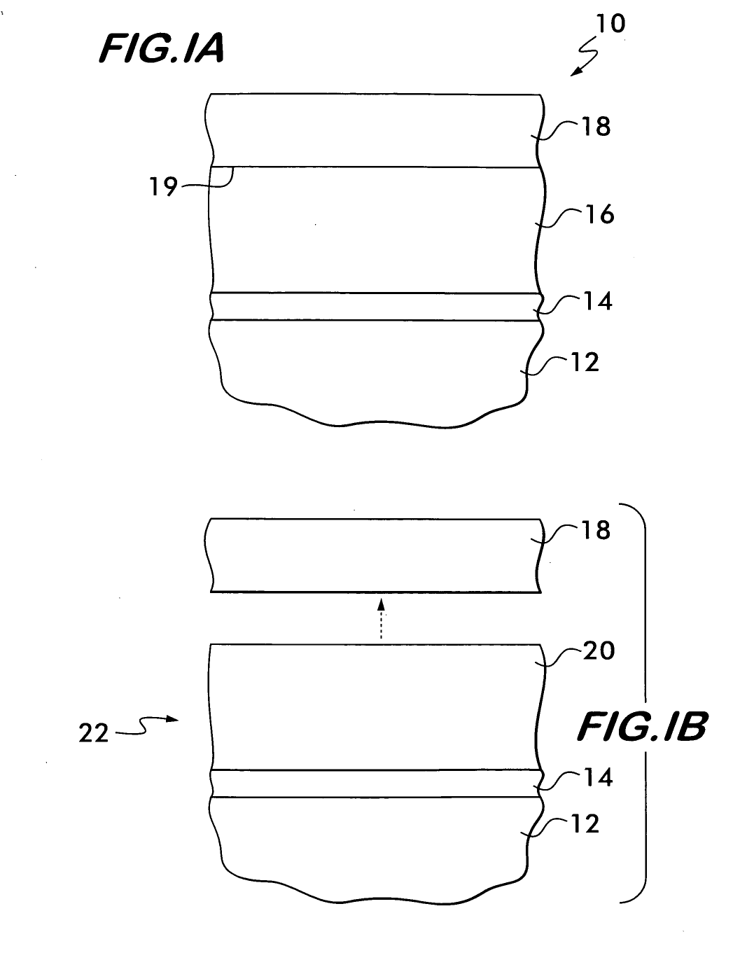

In reference to FIGS. 1A and 1B, an assembly for fabricating a structure having a crystalline film, identified generally by reference numeral 10 is shown for one embodiment of the present invention. The assembly 10 includes a rigid substrate 12, a conductive layer 14 being in operative contact with the rigid substrate 12, a precursor material 16 of the crystalline film being in operative contact with the conductive layer 14, and a flexible substrate 18 as defined herein including a contact surface 19. The contact surface 19 of the flexible substrate 18 is in operative contact with the precursor material 16 opposite from the conductive layer 14. Alternatively, the precursor material 16 may include one or more layers of the same or different precursor materials, where one precursor layer is deposited on the conductive layer 14 and another precursor layer is deposited on the contact surface 19 of the flexible substrate 18. The deposited layers of precursor materials are contacted together to form the precursor material 16.

The one or more layers of precursor material 16 can then interact under the influence of motion, heat, pressure, electrostatic fields, epitaxial forces, surfactants, magnetic fields, and/or catalysts. The precursor material 16 is transformed into a crystalline film (monocrystalline or polycrystalline) 20 forming part of a structure 22 as shown in FIG. 1B. The flexible substrate 18 is then removed from the crystalline film 20 which remains on the rigid substrate 12.

The structure 22 differs from prior art structures which do not employ the flexible substrate 18 in that there are fewer defects in the structure 22. Accordingly, the energy transmission properties of the structure 22 are improved.

The flexible substrate 18 can be a reusable tool composed of, for example, silicon. The contact surface 19 of the flexible substrate 18 can be coated with a release layer (not shown) composed of, for example, calcium fluoride, strontium fluoride, and alloys thereof. The flexible substrate 18 can be used to apply pressure, as a counter-electrode for electrical biasing, and/or as a crystallographic template to control the structure of the precursor structure grown thereupon.

In another embodiment of the present invention, there is provided a method of making a structure having a crystalline film, which includes the steps of obtaining a rigid substrate having a conductive layer disposed in operative contact therewith, applying a first precursor material of the crystalline film on the conductive layer in operative contact therebetween, applying a flexible substrate having a contact surface, wherein the contact surface is in operative contact with the first precursor material opposite from the conductive layer, processing the first precursor material into the crystalline film, and removing the flexible substrate. Optionally, the contact surface of the flexible substrate further includes a second precursor material of the crystalline film in operative contact with the first precursor material.

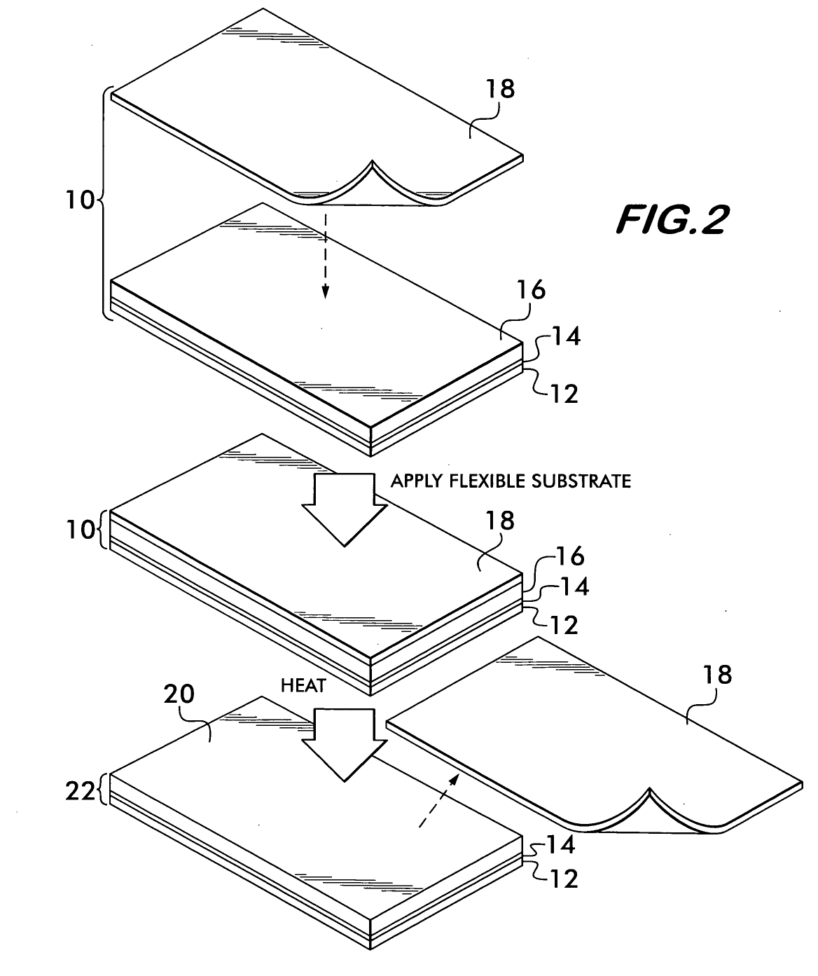

Referring to FIG. 2, the method of the present invention is depicted in accordance with one embodiment of the present invention. An assembly 10 includes a rigid substrate 12 coated or provided with a conductive layer 14. In this embodiment, the rigid substrate 12 is a soda-lime glass having a thickness of from about 1 mm to 3 mm. It will be understood that the same principles of the present invention will apply to rigid substrates of other materials, such as, for example, ceramic substrates having a variety of thickness dimensions. The conductive layer 16 is deposited continuously over the top surface of the rigid substrate 12. In the present embodiment, the conductive layer 16 is molybdenum having a thickness of about 0.3 μm to 0.4 μm.

One or more layers of precursor material 16 are deposited on the surface of the conductive layer 14. The assembly 10 further includes a flexible substrate 18 composed of any suitable material having a suitable thickness to impart low resistance to deformation upon application of a force. Optionally, a precursor material may be deposited on the contact surface of flexible substrate 18 for contact with the precursor material 16 on the rigid substrate 12. The precursor materials may be deposited on rigid substrate 12, and optionally on the flexible substrate 18, in a stacked or laminate arrangement through any suitable methods, including, but not limited to, vacuum deposition techniques, atmospheric-pressure deposition, and the like. For instance, the precursor material can be fabricated by sputtering followed by plasma discharge, particle deposition, physical vapor deposition and/or chemical vapor deposition. In a preferred embodiment of the present invention, one or more layers of precursor material can be fabricated by sputtering of an elemental metal (e.g., copper) followed by plasma discharge of another element (e.g., elemental selenide vapor).

Examples of vacuum deposition techniques include, but are not limited to, chemical vapor deposition (CVD), atomic layer deposition (ALD), chemical solution deposition (CSD), plating, physical vapor deposition (PVD), and the like. Examples of PVD processes include, but are not limited to, thermal evaporation, electron-beam evaporation, ion beam deposition (IBD), molecular beam epitaxy (MBE), pulsed laser deposition, sputtering, and the like. Examples of atmospheric-pressure deposition include, but are not limited to, ultrasonic or pneumatic atomization spraying, inkjet spraying, direct writing, screen printing, slot die extrusion coating, and the like.

In the present embodiment, the precursor material 16 includes a CIGS precursor stack comprising a stack or laminate of thin films composed of multinary (preferably binary and ternary) metal selenides or metal sulfides, where the metals are copper, indium and/or gallium. The flexible film of precursor material containing copper, indium and gallium has a thickness in the range of from about 1.5 μm to 2.5 μm. Although the present method will be described in association with making copper indium gallium selenide (CIGS)-based structures with a rigid substrate, it will be understood that the present method is applicable for making any structures with a rigid substrate utilizing precursor materials including those described above and others.

In a preferred embodiment of the present invention, the contact surface of the flexible substrate 18 is laid continuously in a rolling manner onto the surface of the precursor material 16 from a first end to an opposing second end. The contact surface of the flexible substrate 18 is urged into atomic-level contact with the surface of the precursor material 16 to form the assembly 10. The application of the flexible substrate 18 in operable contact with the precursor material 16 can be carried out under atmospheric pressures or under partial vacuum conditions. Preferably, the application of the flexible substrate 18 is carried out under partial vacuum conditions to eliminate or at least substantially minimize the formation of bubbles between the precursor material 16 and the flexible substrate 18.

The assembly 10 is then processed by heating the precursor material 16 to a reaction temperature optionally in the presence of a precursor vapor such as elemental selenium for a sufficient time to transform the precursor material 16 into a heated precursor material film. The precursor vapor is present at a preselected partial pressure. Alternatively, the elemental selenium content may be included in the precursor material 16. The heating process promotes interaction between the one or more layers of precursor material 16 and the precursor vapor at a preselected partial pressure. At the reaction temperature, the preselected partial pressure of the precursor vapor is in the range of from about 1.0 mTorr to 200 Torr, and preferably from about 1 Torr to 50 Torr.

The resulting combination upon rapidly heating to a sufficient temperature referred herein as “reaction temperature” enables the precursor material and precursor vapor to interact and thereby transform the precursor material 16 into a reaction product 20. The reaction temperature is at least about 100° C., more preferably from about 300° C. to 1000° C., and most preferably from about 400° C. to 700° C. Optionally, the precursor material 16 is preheated to a preheating temperature, preferably at about 100° C.

The heating process promotes interaction between adjacent layers of precursor material 16 and the optional precursor vapor. The interaction can be chemical (e.g., reactants forming a product) and/or physical (e.g., molecular diffusion, two polymers intermingling to form a copolymer or two metals diffusing together to form a solid solution). The precursor material 16 and the precursor vapor are maintained at the reaction temperature for a residence time sufficient to achieve a desired concentration of precursor vapor within the precursor material. In the present invention, the residence time is determined by several factors, including but not limited to, the transport/incorporation/diffusion of precursor vapor, the speed of chemical/physical interaction between precursors, and the desired final property of the reacted film including material concentration gradients, elemental gradients, defect structures, crystal formation, and morphology. The residence time is in the range of from about 1 second to 180 minutes, and preferably from about 2 seconds to 30 minutes.

When the precursor material 16 is rapidly heated to a reaction temperature in the presence of precursor vapor (elemental selenide gas) at a preselected partial pressure for a predetermined residence time, the elemental selenide gas as a precursor vapor supplies a source of selenium needed in the precursor material 16 and provides the necessary overpressure to ensure sufficient content of elemental selenium in the reaction product. In addition, the contact of the flexible substrate 18 on the precursor material 16 provides sufficient mechanical pressure to substantially prevent loss of precursor components (e.g., elemental selenium) from the reaction zone, thereby achieving highly efficient incorporation of the precursor component into the precursor material 16.

In this manner, any selenium released from the precursor material 16 during the heating process is substantially minimized by the contact of the flexible substrate 18 thereon particularly at the final reaction temperatures, thus avoiding selenium deficiency or defects in the final reaction product 20. The residence time in the chamber is controlled in part by the selenium partial pressure and its uniformity of the elemental selenide gas. A non-optimal residence time may yield a non-optimal reaction temperature or heating profile, thus causing inferior chemical composition and/or defect states in the reacted product.

It is noted that the heating process may be implemented in a single stage or in multiple stages depending on the desired characteristics of the final product. The reaction temperature, the precursor vapor, the partial pressure of the precursor vapor, or residence time can be varied or maintained as needed from one stage to the next.

The heated product of the precursor material 16 and optional precursor vapor is then cooled down at a controlled rate to ambient temperature. The flexible substrate 18 is removed to yield the assembly 22 with a resulting crystalline film 20.

It is noted that the cooling process may be implemented in a single stage or in multiple stages. The cooling rate of the heated product is at least 0.5° C./s, preferably in the range of from about 0.5° C./s to 15° C./s, and more preferably, in the range of from about 1° C./s to 5° C./s. Cooling may be achieved by exposing the heated product to an inert gas flux (e.g., nitrogen gas).

Optionally, the heated product is cooled to a temperature above ambient while remaining in the presence of the precursor vapor. During this cooling step exposure to the precursor vapor may continue at the same or different partial pressure. In a preferred embodiment of the present invention, when the heated product is at a temperature of from about 325° C. to 675° C., the partial pressure of the precursor vapor is in the range of from about 1.0 mTorr to 200 Torr, and more preferably in the range of from about 1.0 mTorr to 50 Torr. At the temperature of from about 0° C. to 325° C. for the heated product, the partial pressure of the precursor vapor is in the range of from about 0 mTorr to 1 Torr, and more preferably in the range of from about 0 mTorr to 1 mTorr.

The present invention can further include subsequent processing of the crystalline film 20. For instance, the crystalline film 20 can be post-process heated in an atmosphere (e.g., air or oxygen) to tailor the defect structure and/or improve performance. This post-processing heating in an atmosphere can be termed annealing.

The present invention can include devices that incorporate the resulting crystalline film 20 (e.g., photovoltaic devices that contained the crystalline film as an absorber layer). Further, the invention can also include systems that include such devices. The invention can include equipment for forming the crystalline film 20.

In particular, the structure 22 can then be further processed with the crystalline film 20 as the absorber material (e.g., CIGS layer) formed on the conductive layer 14 to yield a photovoltaic device structure. The photovoltaic device structure is completed by deposition of a transparent conductive layer (not shown) including a buffer layer (not shown) over the nanostructured crystalline film 20. The buffer layer is generally a sulfide compound such as indium sulfide. The transparent conductive layer is may be a transparent conductive oxide (TCO) (e.g., ZnO). A grid pattern (not shown) of conductive metal is then deposited on the transparent conductive layer.

The foregoing discussion discloses and describes merely exemplary embodiments of the present invention. One skilled in the art will readily recognize from such discussion, and from the accompanying drawings and claims, that various changes, modifications and variations can be made therein without departing from the spirit and scope of the invention as defined in the following claims.

What is claimed:

1. An assembly for fabricating a structure having a crystalline film, said assembly comprising:
a rigid substrate;
a conductive layer being in operative contact with the rigid substrate;
a first precursor material of the crystalline film being in operative contact with the conductive layer; and
a flexible substrate including a contact surface, said contact surface of the flexible substrate being in operative contact with the first precursor material opposite from the conductive layer.

2. The assembly of claim 1 wherein the first precursor material is selected from the group consisting of Group I elements, Group II elements, Group III elements, Group IV elements, and Group VI elements, and combinations thereof and compounds thereof.

3. The assembly of claim 1 wherein the contact surface of the flexible substrate further comprises a second precursor material of the crystalline film in operative contact with the first precursor material.

4. The assembly of claim 3 wherein the second precursor material is selected from the group consisting of Group I elements, Group II elements, Group III elements, Group IV elements, and Group VI elements, and combinations thereof and compounds thereof.

5. The assembly of claim 1 wherein the contact surface of the flexible substrate is nanostructured.

6. The assembly of claim 1 wherein the conductive layer is selected from the group consisting of molybdenum, titanium, tungsten, tantalum and combinations thereof.

7. A method of making a structure having a crystalline film, said method comprising the steps of:
obtaining a rigid substrate having a conductive layer disposed in operative contact therewith;
applying a first precursor material of the crystalline film on the conductive layer in operative contact therebetween;
applying a flexible substrate having a contact surface, wherein the contact surface is in operative contact with the first precursor material opposite from the conductive layer;
processing the first precursor material into the crystalline film; and
removing the flexible substrate.

8. The method of claim 7 wherein the contact surface of the flexible substrate comprises a second precursor material of the crystalline film in operative contact with the first precursor material.

9. The method of claim 7 wherein flexible substrate applying step comprises laying the contact surface of the flexible substrate continuously against the surface of the first precursor material from a first end to an opposing second end thereof.

10. The method of claim 7 wherein the flexible substrate applying step is carried out under vacuum.

11. The method of claim 7 further comprising removing the flexible substrate upon forming the crystalline film from the first precursor material.

12. The method of claim 7 wherein the contact surface of the flexible substrate is nanostructured.

13. The method of claim 7 wherein the processing of the precursor material comprises:
heating the first precursor material to a reaction temperature for a sufficient time to form a heated precursor material; and
cooling the heated precursor material to yield the crystalline film.

14. The method of claim 13 wherein the reaction temperature is at least about 100° C.

15. The method of claim 14 wherein the reaction temperature is in the range of from about 300° C. to 1000° C.

16. The method of claim 15 wherein the reaction temperature is in the range of from about 400° C. to 700° C.

17. The method of claim 13 wherein the heating time is in the range of from about 1 second to 180 minutes.

18. The method of claim 13 wherein the heated precursor material is cooled at a predetermined cooling rate.

19. The method of claim 18 wherein the cooling rate is in the range of from about 0.5° C./s to 15° C./s.

20. The method of claim 19 wherein the cooling rate is in the range of from about 1° C./s to 5° C./s.

21. The crystalline film structure made by the method of claim 7.

22. A crystalline film structure, comprising:
a rigid substrate;
a conductive layer being in operative contact with the rigid substrate; and
a first precursor material of the crystalline film having a flexible substrate treated surface in operative contact with the conductive layer.

23. A method of making an assembly for fabricating a structure having a crystalline film, said method comprising the steps of:
obtaining a rigid substrate having a conductive layer disposed in operative contact therewith;
applying a first precursor material of the crystalline film on the conductive layer in operative contact therebetween; and
applying a flexible substrate having a contact surface, wherein the contact surface is in operative contact with the first precursor material opposite from the conductive layer.
